(19) United States
(12) Patent Application Publication
(10) Pub. No.: US 2006/0285374 A1
(43) Pub. Date: Dec. 21, 2006

(54) Content addressable memory cell

(76) Inventors: Clement Szeto, Union City, CA (US); Hock C. So, Saratoga, CA (US); Ting-Wah Wong, Cupertino, CA (US); Masaharu Shinya, Tokyo (JP)

Correspondence Address: TROP PRUNER & HU, PC, 1616 S. VOSS ROAD, SUITE 750, HOUSTON, TX, 77057-2631, US

(21) Appl. No.: 11/154,877

(22) Filed: Jun. 16, 2005

(51) Int. Cl. G11C 15/00

(52) U.S. Cl. 365/49

(57) ABSTRACT

A content addressable memory cell may include a non-volatile memory storage transistor coupled to an enhancement transistor. In some embodiments, the enhancement transistor may be a select cell. In some embodiments, the storage transistor may use substrate hot electron injection. Through the use of the enhancement transistor, overerasing and read disturb problems may be mitigated.

### BACKGROUND

This invention relates generally to content addressable memory (CAM) cells.

Content addressable memory cells may be utilized in various applications. In one application in a router, a stored Internet Protocol (IP) address may be matched with an address from incoming data. Because the CAM cell stores a large amount of data that can be simultaneously compared with input data, it is particularly suitable for use in routing applications.

Conventionally, the CAM cells are arranged in an array whose rows correspond to stored words. Thus, each row of the array is coupled to a word line and a match line. Any of the rows may be selected to write to one or more of the cells in the row. The match line indicates whether a word stored in a row matches the input data for comparison purposes.

Generally, in a search protocol, complementary signals are applied to a pair of bitlines. These complementary signals represent one of a plurality bits of the input signal. The CAM cell associated with each bit changes the voltage on the match line depending on whether or not the CAM cell stores a bit that matches the bit presented on the associated bitlines.

CAM cells use a variety of different memory technologies. Static Random Access Memory (SRAM) and Dynamic Random Access Memory (DRAM) based cells are volatile and, therefore, require a more tedious initialization process to load the contents of the CAM cells from an external nonvolatile source such as an external Flash memory. This leads to extra cost and extra board area in the system. Thus, nonvolatile CAM cells may be more desirable.

Flash memory may also be utilized in connection with CAM cells. However, Flash memories are susceptible to some distinct disadvantages. Conventional stacked-gate Flash cells may be subject to an overerasing problem. The double poly Flash storage transistor may leak current even when its gate is grounded when overerasing occurs. Thus, an overerased but unselected Flash memory cell may affect the sensing of other selected Flash memory cell(s) sharing the same column (bit line). An elaborate control scheme is usually needed to monitor the erase process in order to prevent overerasing from occurring. This again leads to larger die area and extra cost.

In addition, some Flash memory cells have relatively low cell current. The cell current is a primary determinant of cell speed. Thus, Flash cells may tend to be slower, in some cases, than corresponding SRAM or DRAM cells.

Finally, using Flash memory as the memory of a CAM cell may raise a read disturb problem. With Flash memory used in a CAM cell, the drain of the storage transistor generally sees the full Vcc voltage. For a programmed cell with negative charges (electrons) stored in the floating gate, there is a strong electric field between the floating gate and the drain, which creates a read disturb issue. It is more desirable to limit the drain voltage of the storage transistor during the read (compare) operation.

Thus, there is a need for improved content addressable memory cells.

### BRIEF DESCRIPTION OF THE DRAWINGS

FIG. 1 is a schematic depiction of a content addressable memory array in accordance with a first embodiment of the present invention;

FIG. 2 is a schematic depiction of one embodiment of a cell useful in the embodiment shown in FIG. 1;

FIG. 3 is a schematic depiction of a CAM array in accordance with a second embodiment of the present invention;

FIG. 4 is a schematic depiction of a cell that may be utilized in one embodiment of the array shown in FIG. 3;

FIG. 5 is a schematic depiction of a cell which may be used in another embodiment of the array shown in FIG. 3;

FIG. 6 is a schematic depiction of one embodiment of a flash memory cell;

FIG. 7 is an enlarged cross-sectional view through storage and select transistors that may be used in accordance with one embodiment of the array shown in FIG. 1;

FIG. 8 is an enlarged cross-sectional view taken transversely through the storage transistor 12 shown in FIG. 6 in accordance with one embodiment of the present invention; and

FIG. 9 is an enlarged cross-sectional view through the storage and select transistor in accordance with one embodiment of a Flash memory useful in the embodiment shown in FIG. 3.

### DETAILED DESCRIPTION

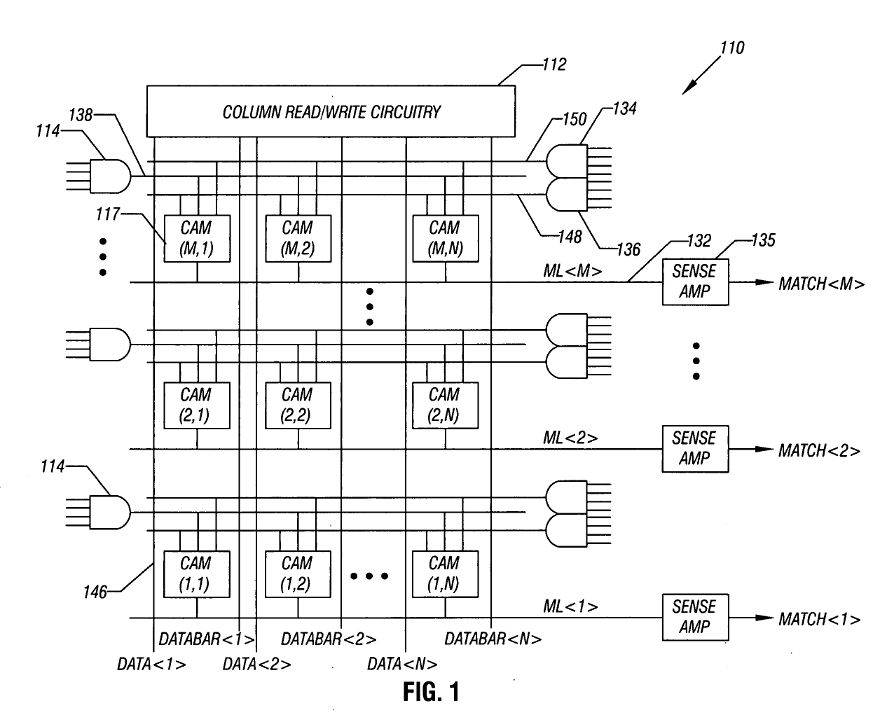

Referring to FIG. 1, a content addressable memory (CAM) array 110 includes column read/write circuitry 112 coupled to pairs of bit or data lines 146 indicated as data and data bar 1 through N. Each word line 138 is coupled to a word line decoder 114. Each injector line 150 is coupled to an injector decoder 134. The injector line 150 is used to control the injection of substrate hot electrons during programming. A plurality of CAM cells 117 are arranged in an array 110 beginning with the CAM cell (M, 1) and ending in a CAM cell (1, N), the array having M rows and N pairs of bitline columns. A sense amplifier 135 is coupled to each CAM cell through its match line 132. Thus, there are 1 through M match lines 132, each coupled to a separate sense amplifier 135.

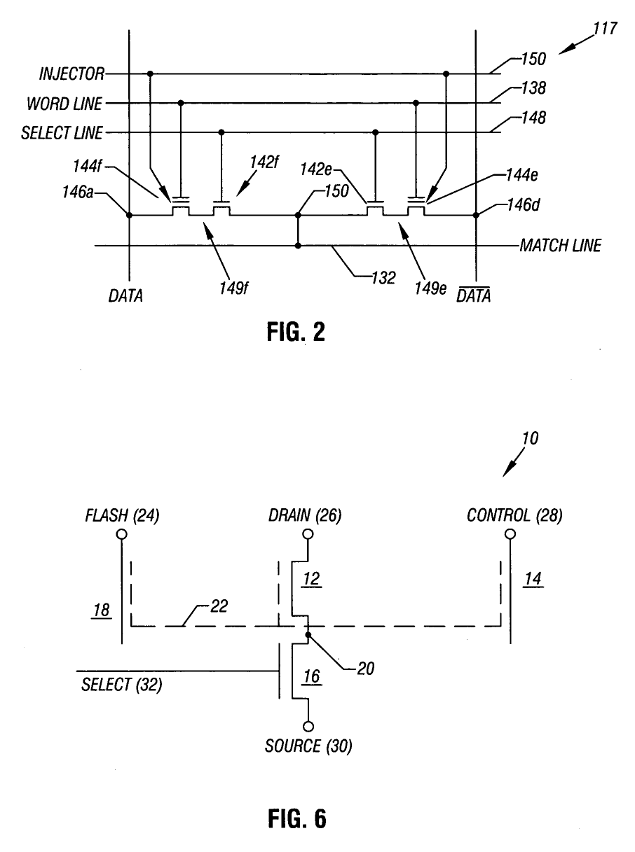

Referring to FIG. 2, a single polysilicon CAM cell 117 may include an injector line 150, a word line 138, a select line 148, and a pair of Flash cells 149e and f, each including a storage transistor 144e or f and a select transistor 142e or f. Each storage transistor 144 is coupled to either the data line or the data bar line 146. A central node 150, between the two Flash cells 149, is coupled to the match line 132.

In one embodiment, the word line 138 may be pulsed to the supply voltage Vcc (e.g. 1.8 or 3 volts) for the compare operation and may be set to Vcc for the read operation. For programming, the word line 138 voltage may be higher, for example, approximately 11.5 volts. For erasing the word line 138, the voltage may be set to Vss as one example.

The select line 148 may be pulsed to a high voltage level, such as Vcc, in one embodiment for the compare operation. The select line may stay at voltage such as Vcc for reading and Vss for programming and erasing in one embodiment.

The match line 132 may be precharged to a high voltage level (e.g. Vcc) for the compare operation. The match line 132 may be biased to a lower voltage, such as Vss, for reading. The match line 132 may be biased to Vss for programming and erasing in one embodiment.

The data and data bar signals are complementary signals which may be Vcc and Vss, in one embodiment, during the compare operation. The data line 146 may be 0.5 to 1.0V for the cell being read while the data bar line 146 is open for the first cell 149f and vice versa for the second cell 149e. During programming of the first cell, the data line may be about 5 volts while the data bar line is Vss, and vice versa for the other cell.

The storage transistors 144 may be programmed to opposite states. Thus, the storage transistor 144f may be equal to one or the erased state while the storage transistor 144e is set to zero or the programmed state, or vice versa. However, in some cases, it is also possible that both storage cells 144 are programmed so that the bit becomes a “don't care” state.

In a compare operation, the external address data are compared to the data stored in the CAM cell. If the storage transistor 144f has a one value, indicating it is erased, and the value on the data node 146a is equal to one, while the storage transistor 144e has a zero state, indicating it is programmed, and data bar is zero, then there is a match and the match line 132 stays high. Conversely, if the storage transistor 144f has a zero state indicating it is programmed, the data node 146a is equal to one and the storage transistor 144e is equal to one, indicating it is erased, while the data bar is zero, then there is no match and the match line 132 is discharged to ground through the storage transistor 144e. The possible compare combinations are as follows:

| Stored | CAM Cell | CAM Cell | Input | | | Match | |
|---|---|---|---|---|---|---|---|
| Bit | 149f | 149e | Bit | Data | DataBar | Line | Result |
| 0 | Programmed | Erased | 0 | Vss | High | High | Match |
| 0 | Programmed | Erased | 1 | High | Vss | Dips | No Match |
| 1 | Erased | Programmed | 0 | Vss | High | Dips | No Match |
| 1 | Erased | Programmed | 1 | High | Vss | High | Match |
| X | Programmed | Programmed | 0 | Vss | High | High | Match |
| X | Programmed | Programmed | 1 | High | Vss | High | Match |

If both storage transistors 144 are equal to zero, indicating they are both programmed, then the match line 132 stays high regardless of the value on the data lines 146. Thus, the CAM bit becomes a don't care bit.

Multiple CAM bits are connected in parallel, sharing the same word line 138. The match line 132 stays high if, and only if, all the individual CAM bits are matching the values on the data and data bar lines 146.

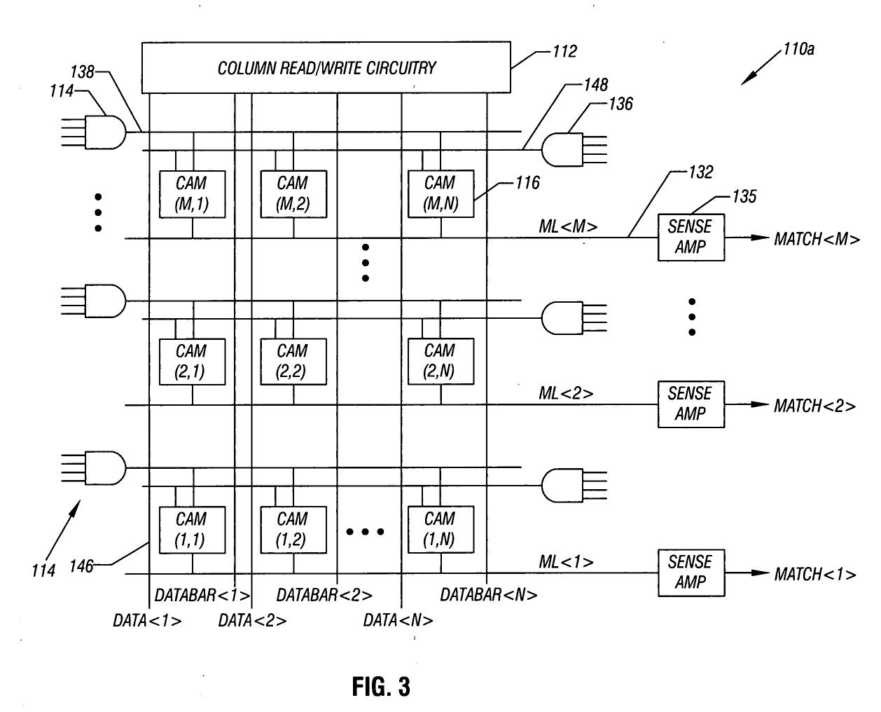

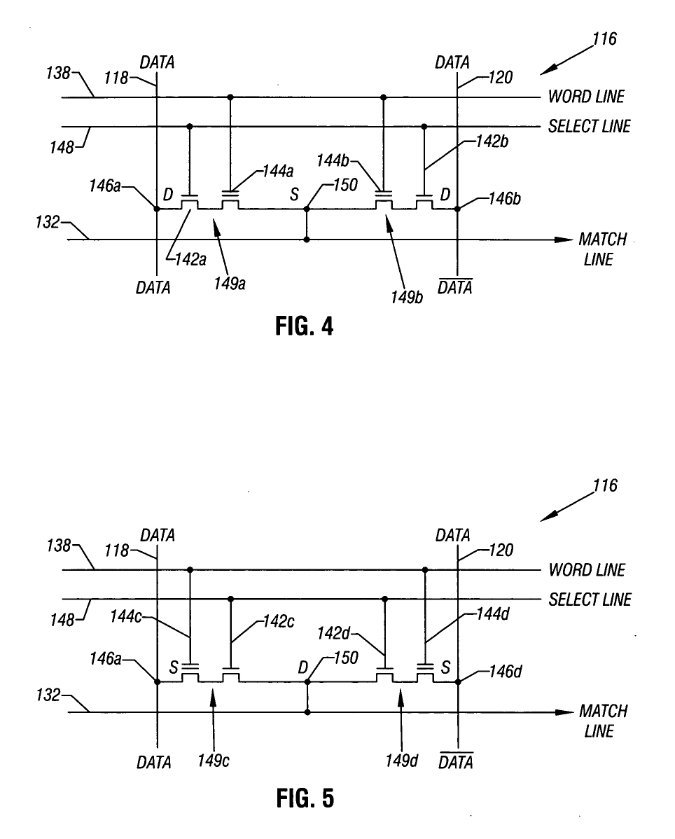

Referring to FIG. 3, a double polysilicon content addressable memory array 110a is similar to the embodiment shown in FIG. 1, but an injector line is not used. In one embodiment, the sources of the storage transistors 144a and 144b are coupled at the node 150, as shown in FIG. 4. In another embodiment, as shown in FIG. 5, the drains of the select transistors 142c and 142d are coupled at the node 150 while the sources of the select transistors are coupled to the data and data bar lines 146. Still other arrangements are possible.

In the compare mode, the word line 138 is biased to Vcc, the select line 148 may be pulsed to a high voltage, such as Vcc, the match line 132 may be precharged to a high voltage, such as Vcc, the data line 146 may be either high or Vss, and the data bar line 146 is either Vss or high, in one embodiment of the present invention. The match line 132 stays high if all bits match, but the match line dips to less than about 5 volts, in one embodiment, if there is a mismatch between any bits in the array 110a.

To read the non-volatile memory cell 149a or 149c, including storage transistor 144a or 144c (FIGS. 4 and 5), the word line 138 and the select line 148 may be Vcc, the match line 132 may be Vss, while the data line 146 may be between 0.5 and 1V and the data bar line 146 may be open, in one example. To read the cell 149b or 149d, including the storage transistor 144b or 144d, the word line, select line, and match line are the same as before, but now the data line is open and the data bar line is between 0.5 and 1V in one embodiment. The match line is Vss in one example.

To program the cell 149a or 149c, the word line 138 may be set to about 11.5 volts, the select line 148 may be biased to about −1 volt, the match line 132 may be biased to about −1 volt, while the data line 146 is approximately 5 volts and the data bar line 146 is Vss, in one example. Similarly, to program the cell 149b or 149d, the word line, select line, and match line are the same as before but now the data line is set to Vss and the data bar line is approximately 5 volts, in one embodiment.

To erase either of the cells 149 of an array cell 116, the word line is set to Vss, the select line is set to Vss, the match line is approximately −11 volts, the data line is approximately 6 volts, and the data bar line is approximately 6 volts, in one example. In one embodiment all cells 116 in the same row may be erased together.

Because of the use of a select transistor 144, the over-erasing problem can be lessened or even eliminated in some embodiments. By controlling the bias applied to the select line, and maintaining it between 0.5 and 2 volts, for example, the voltage at the nodes between the select and storage transistors is limited to about 1 volt or below, thereby substantially reducing the read disturb problem. Without the series select transistor, the drain of the storage transistor would see a full Vcc voltage swing.

In some embodiments the cells 116 may be formed with Flash storage transistors 10 that use substrate hot electron (SHE) injection. However, other types of non-volatile memory can be used, including Flash memories using convention electron injection, a non-volatile random access (NV RAM) memory, or an electrically erasable programmable read only memory (EEPROM).

A single-poly substrate hot electron injection memory cell 10, shown in FIG. 6, includes a tunneling capacitor 18, a sense transistor 12, a select transistor 16, and a coupling capacitor 14. This structure is advantageously implemented on a semiconductor layer having situated thereon an electrically isolated floating gate 22.

The tunneling capacitor 18 is controlled by the flash node 24, and the coupling capacitor 14 is controlled by the control node 28. The drain 29 of the sense transistor 12 is connected to the drain node 26 and the source 31 of select transistor 16 is connected to the source node 30. The gate 33 of the select transistor 16 is connected to the select node 32.

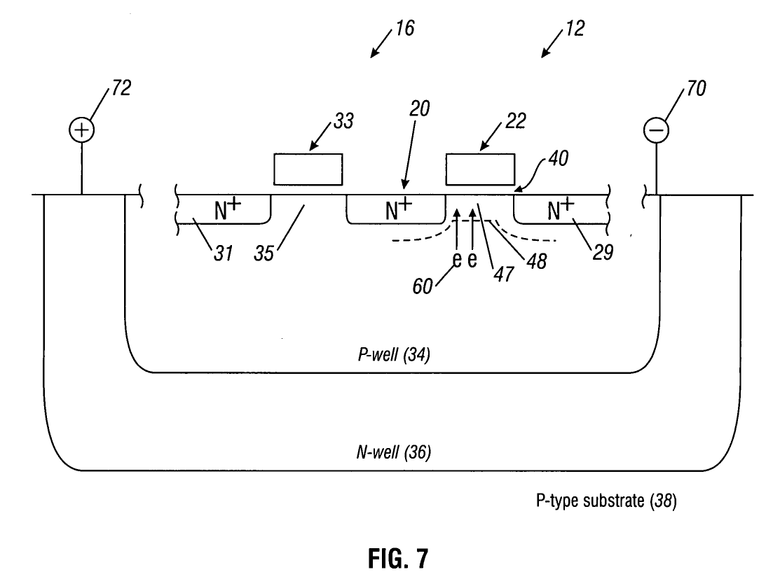

The floating gate 22 forms the gate of a transistor having a drain 29 and a common junction 20 as shown in FIG. 6. Similarly, the gate 33 in FIG. 7 acts to control conduction between the source 31 and the common junction 20. The sense transistor 12 includes a channel 47 while the select transistor 16 includes a channel 35. In the illustrated embodiment, the channels 47 and 35 are P-type semiconductor material and are part of a P-well 34. The P-well 34 in turn is formed in an N-well 36. Finally, the N-well 36 is formed in a P-type substrate 38, biased at reference voltage Vss. The P-well may be negatively biased, as indicated at 70, and the N-well 36 may be positively biased, as indicated at 72. The N-well 36 may be biased to a potential equal to or more positive than Vss.

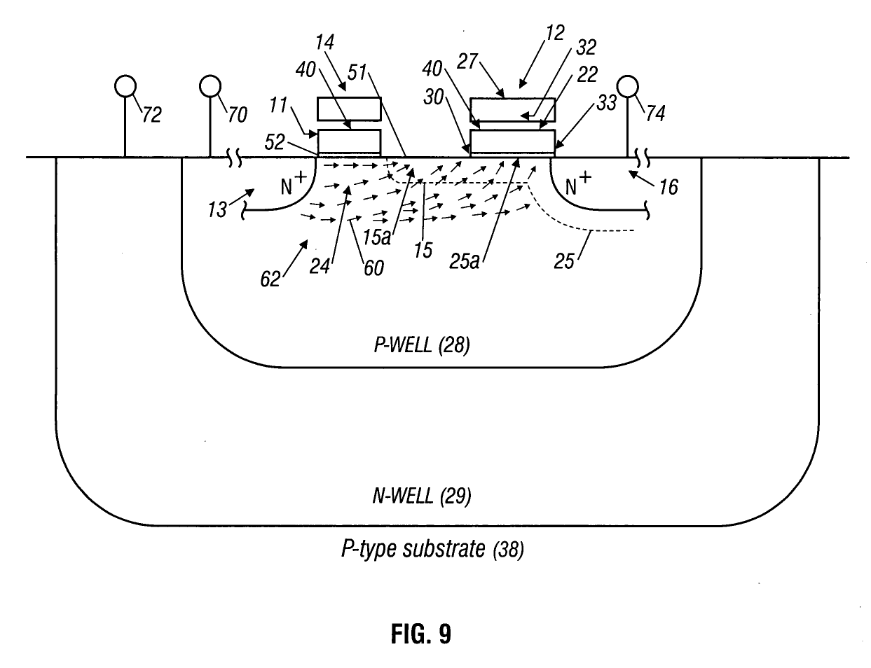

Referring now to FIG. 9, the configuration of the floating gate 22 in connection with the tunneling capacitor 18 and coupling capacitor 14 can be explained. The floating gate 22 extends over a pair of field oxide regions 50 which extend generally parallel to the source-to-drain direction of the sense transistor 12 and select transistor 16. At one end in FIG. 7, the floating gate 22 forms the tunneling capacitor 18 by its interaction with the underlying region 25 which may be an N+ diffusion. A tunneling oxide 42 separates the floating gate 22 from the diffusion 25. Similarly the gate oxide 40 separates the floating gate 22 from the channel 47. Finally, the floating gate 22 is separated by the oxide 51 from the diffusion 27 of the coupling capacitor 14. Thus, the floating gate 22 is part of the sense transistor 12 and the capacitors 14 and 18.

The cell 10 may be described as a flash EEPROM utilizing high efficiency substrate hot electron injection for programming and Fowler-Nordheim tunneling for erasure. The process of substrate hot electron injection is well described in T. H. Ning, C. M. Osburn, and H. W. Yu, “Emission Probability of Hot Electrons from silicon Into Silicon Dioxide”, J. Appl. Phys., Vol. 48, p. 286, (1977); Boaz Eitan, James L. McCreary, Daniel Amrany, Joseph Shappir, “Substrate Hot-electron Injection EPROM”, IEEE Transactions On Electron Devices, Vol. ED-31, No. 7, p. 934, (July 1984); I. C. Chen, C. Kaya, and J. Paterson, “Band-to-Band Tunneling Induced Substrate Hot-electron (BBISHE) injection: A New Programming Mechanism For Nonvolatile Memory Devices”, IEDM (1989) p. 263; and C. Y. Hu, D. L. Kencke, S. K. Benerjee, “Substrate-current-induced Hot Electron (SCIHE) Injection: A New Convergence Scheme For FLASH Memory,” IEDM (1995), p. 283. Each of these articles is hereby expressly incorporated by reference herein.

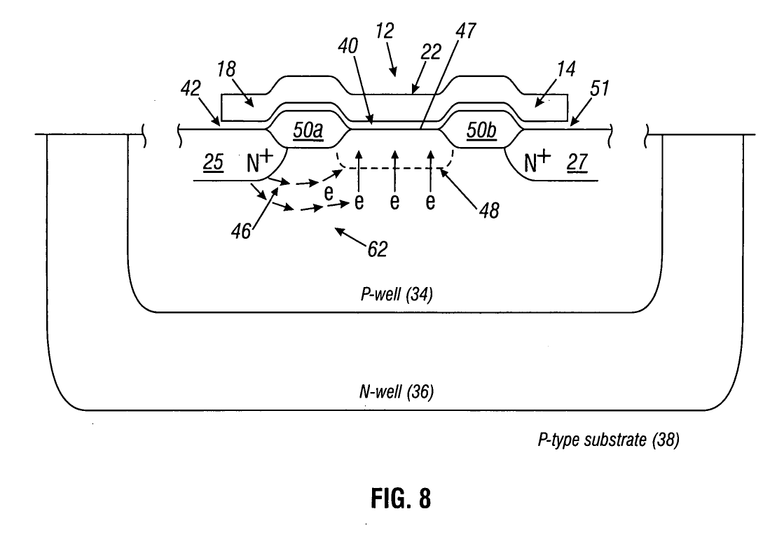

Programming is achieved by high efficiency substrate hot electron injection. As indicated in FIGS. 7 and 8, substrate electrons, indicated at 60, are generated by forward biasing the diffusion 25 which is separated from the sense transistor 12 by the field oxide 50a. Some of the substrate electrons 46 diffuse through the region underneath the field oxide 50a to the channel region 47 underneath the sense transistor 12. For cells that need to be programmed, the channel region 47 is biased such that a depletion region 48 is formed. When an electron gets to the depletion region 48, it is accelerated by an electric field created by the voltage difference Vcs between the channel 47 potential (potential of the surface inversion region) and the P-well 34 potential. Some of these electrons gain sufficient energy, in excess of the effective oxide barrier height potential, to be injected onto the floating gate 22. For cells that are not to be programmed, the channel-to-P-well potential is less than the effective oxide barrier height. In such case, the electrons would not gain sufficient energy to overcome the barrier height and are not injected onto the floating gate 22.

The diffusion 25, the P-region under the field oxide 50a and the biased depletion region 48 under the sense transistor 12 form a lateral bipolar transistor 62. The bipolar transistor 62 acts as a charge injector, injecting substrate electrons from the diffusion 25 onto the floating gate 22. With the diffusion 25 as the emitter, the P-region under the field oxide 50a as the base, the collector is the depletion region 48. The depletion region 48 is controlled by the N+ source 20 and N+ drain 29, and the P-well 34 potential. Since the channel region 47 acts as the channel for reading the sense transistor 12 and as the collector of the bipolar transistor 62 during programming, a compact cell layout is achieved.

The efficiency of substrate hot electron injection is a function of a number of characteristics. In the depletion region 48, electrons scatter with lattice phonon scattering across the depletion region 48 with a certain electron mean free path. Some of these electrons without much scattering, gain sufficient energy to overcome the effective barrier height and are injected onto the floating gate 22. Some electrons gain less energy than the effective barrier height and are not injected onto the floating gate 22. The injection efficiency is a strong function of the doping concentrations and the channel-to-P-well potential, Vcs.

Since the cell 10 is situated in a P-well 34 embedded in an N-well 36, during programming the floating gate 22 is capacitively coupled to a higher voltage through the coupling capacitor 14 by raising the diffusion 27 to Vpp, which may be from 7 to 14 volts. The voltage that the floating gate 22 attains is a function of the voltage on the floating gate when the nodes 24, 26, and 28 are at ground, plus the coupling ratio times the voltage on the node 28. The coupling ratio to first order is approximately equal to the capacitance of the capacitor 14 divided by the sum of the capacitances of the coupling capacitor 14, the tunneling capacitor 18 and the capacitance between the floating gate 22 and the channel region 47.

When the select transistor 16 is off, the sense transistor drain 29 potential can be forced close to the supply potential Vcc or higher. Since the select transistor 16 is off, the source 20 potential follows the channel 47 potential. The channel 47 potential is the potential of the surface inversion region of the channel region. When the potential of the floating gate 22 is one sense transistor 12 threshold voltage higher than the drain 29 potential, the channel potential is the same as the drain potential. On the other hand, when the floating gate 22 potential is less than the drain 29 potential plus the sense transistor 12 threshold voltage, the channel potential is the difference between the floating gate 22 voltage and the sense transistor 12 threshold voltage.

The well potential is the voltage 70 applied to the P-well 34. Since the P-well is embedded in an N-well 36, and the N-well is set at a voltage 72 approximately Vss or higher, the P-well potential Vp can be biased negatively, typically negative one to negative two volts. Moreover, it is usually less than the effective oxide barrier height to avoid any potential disturb problem.

The potential difference between the channel 47 region and the P-well 34 potential (Vp) 70 is the voltage across the depletion region 48. For cells to be programmed, the drain 29 voltage is raised high, typically close to Vcc or higher. A depletion region 48 in channel 47 underneath the sense transistor 12 is formed with a voltage drop equal to the channel potential minus the P-well potential 70.

For those cells that are not to be programmed, the drain voltage 29 is set to zero volts. The voltage drop across the depletion region 48 then is equal to the absolute value of Vp, which is typically less than the effective oxide barrier height.

Erasure is achieved by Fowler-Nordheim tunneling from the floating gate 22 to the node 24. The node 24 is therefore called the flash node. During erasure, the floating gate 22 is capacitively coupled through the capacitor 14 to a potential close to ground by forcing the diffusion 27 to ground. As for the diffusion 25, it is charged to a positive potential (Vpp) of from 7 to 14 volts. The voltage across the capacitor 18 is the difference between the floating gate 22 potential and the diffusion 25 potential. When the difference exceeds 8 to 10 volts, sufficient tunneling current is generated and the floating gate 22 can be erased to a negative potential in the time frame of a few milliseconds to a few tens of microseconds depending on the tunneling oxide 42 thickness.

Reading the programmed state of the cell may be accomplished as follows. For the selected row the floating gate 22 is capacitively coupled to a higher potential by forcing the diffusion 27 to a potential of 1.8 to 5 volts. The floating gate 22 is coupled to a potential Vfg which can be calculated as being equal to the sum of the floating gate potential when nodes 24, 26, and 28 are held at ground, plus the potential on the control node 28 times the coupling ratio.

The drain potential during reading is typically limited to a voltage of less than 2 volts. This is to avoid any read disturb.

For the selected cell to be read, the select node 32 is forced to Vcc, and the source node 30 is forced to ground. The unselected gates 33 and the nodes 28, 30 and 32 are also forced to ground.

When these potentials are applied to the selected cell, a current flows through the sense transistor 12. This current is then fed to a current sense amplifier (not shown) biased with a reference cell current, such as 10 μA. If the voltage of the floating gate 22 is greater than the threshold voltage on the sense transistor 12, and a current higher that the reference current flows, the cell state is detected as the conducting state. When the potential of the floating gate is less than the threshold voltage, a lower current, for example less than one microamp flows, and a nonconducting state is detected.

A detected conducting state can be called a one state. A nonconducting state can be called the zero state.

The operation of the cell in programming, reading and erasing, for an exemplary embodiment, is summarized in the following example:

Cell Operation

| | |
|---|---|
| (Selected) | (Unselected) |

Erase

| | | |
|---|---|---|
| FLASH (24) | Vpp | Vss |
| Drain (26) | Float | Float |
| Source (30) | Float | Float |
| Select (32) | Vss | Vss |
| Control (28) | Vss | Vss |
| N-well (36) | Vcc | Vcc |
| P-well (34) | Vss | Vss |

Program

| | | |
|---|---|---|
| FLASH (24) | Vs | Vs or Vss |
| Drain (26) | ≧Vcc | *0 or ≧Vcc |
| Source (30) | Float | Float |
| Select (32) | Vss | Vss |
| Control (28) | Vpp | Vss |
| N-well (36) | Vcc to −2 | Vcc to −2 |
| P-well (34) | Vss to −2 | Vss to −2 |

Read

| | | |
|---|---|---|
| FLASH (24) | Vss | Vss |
| Drain (26) | <−1.5 V | *0 or <−1.5 V |
| Source (30) | Vss | Vss |
| Select (32) | Vcc 2-5 V | Vss |
| Control (28) | Vcc | Vss |
| N-Well (36) | Vcc | Vcc |
| P-well (34) | Vss | Vss |

*0 is for an unselected column.

Vs is the node voltage set by the injection current level, which ranges from a few nanoamps to a few tens of microamps depending on the programming speed requirement. Typically it would be from tens of milliseconds to tens of microseconds. The bias Vbias on the P-well 34 can be Vss or it can be forced to −1 to −2 volts to enhance injection efficiency. A suitable on-chip circuit for generating two negative bias potentials, one to bias the diffusion 31 and the other to negatively bias the P-well 34, can be found in L. A. Glasser and D. W. Dobberpuhl, “The Design and Analysis of VLSI Circuits”, (December 1985), published by Addison-Wesley, at pages 301-329, hereby expressly incorporated by reference herein. Vss is the external ground potential.

The cells in the array may be formed using conventional process technologies such as a single poly, double metal CMOS process. Because there is no control gate polysilicon electrode, a process technology that is completely compatible with normal logic process technology may be utilized.

The illustrative parameters set forth herein contemplate a 0.35 μm or higher feature size with Vcc potentials of 2.7 volts or higher. As the technology permits lowering voltages and smaller feature sizes, the parameters herein would scale accordingly.

The starting substrate material is typically P-type (100) silicon, for example having a resistivity range of 10-25 ohm-cm. The P-well 34 is embedded in an N-well 36 in the so-called triple well process. The P-well 34 has a typical well depth of, for example, 2 to 4 μm with an average doping concentration, for example, in the range of 1×10¹⁶ to 5×10¹⁶ atoms per cubic centimeter.

The N-well 36 has a typical well depth of, for example, 4-8 μm. The doping concentration may be from 4×10¹⁵ to 1×10¹⁶ atoms per cubic centimeter. The triple well is formed by the P-well 34 counterdoping the N-well 36.

The formation of the elements in the triple well is as follows. An N-well implant is done, for example, with phosphorous (P₃₁) with a typical dose of 1.0 to 1.5×10¹³ atoms per square centimeter and energies from 160 Kev to about 100 Kev. The N-well implant is driven using a high temperature step which may typically be 6 to 12 hours at 1125° to 1150° C. The N-well 36 is then counterdoped with a P-well implant. Typical dosages for the P-well implant could be 1.5 to 2.5×10¹³ atoms per square centimeter with energies of 30 Kev to 180 Kev using a species such as boron (B11).

The N-well 36 and P-well 34 are then driven, typically 6 to 10 hours at 1125° to 1150° C. This sets the well to the desired doping concentrations and depths.

After well formation, standard logic field oxide formation and channel stop formation steps are applied. The field oxide 50 and implant doses are adjusted to achieve a field threshold of 7 to 14 volts, which is determined by the Vpp level for programming and erasing and by logic process capability. After field oxide and channel stop formation, the capacitor N+ diffusions 25 and 27 are formed using an ion implant capacitor, such as a phosphorus implant, with an energy of 30-60 Kev and a dose of 1.2×10¹⁴ to 2.5×10¹⁴ atoms per square centimeter. This may be followed by an anneal cycle of 925° to 1000° C. for 15 to 35 minutes.

After the formation of the N+ diffusions 25 and 27, the gate oxide 40 and the tunnel oxide 42 are formed. For example, a 70 to 90 A dry oxide may be grown across the wafer followed by a resist masking step. The resist may cover everything except the tunnel oxide 42 region and the periphery N channel and P channel regions. The N and P channel threshold adjustment implants are then done into all the areas that are not covered by resist. A buffered oxide etch (BOE) is used to etch off the oxide in the region that is not covered by resist. After resist removal, a dry oxide is grown to a thickness 85 to 100 Angstroms, for example, at 900° C. in partial oxygen followed by a 975° to 1050° C. anneal. This forms a gate oxide 40 with a typical thickness of 120 to 150 Angstroms and a tunnel oxide 42 of 85 to 100 Angstroms.

The floating gate 22 may then be formed of polysilicon, silicide or metals after the oxide 40 has been grown. Standard gate patterning is used and source/drain implant steps follow the gate patterning. This sequence forms two capacitors and two transistors. The tunnel oxide 42 is sandwiched between two electrodes, the N+ diffusion 25 and the floating gate 22. This forms the tunneling capacitor 18. The gate oxide 51 sandwiched between the floating gate 22 and the N+ diffusion 27 forms the coupling capacitor 14. The gate oxide 40 that is sandwiched between the floating gate and the channel region 47 forms the sense transistor 12. The select transistor 16 is formed by the gate oxide 40 and the select gate 33.

With the completion of these capacitor and transistor structures, all subsequent processing for contacts and interconnect layers follows standard logic rear end processing.

The relationship of the sense transistor 12 and select transistor 14 for a cell using double poly substrate hot electron Flash cells is illustrated in FIG. 8. The floating gate 22 forms portions of the transistor which has a drain 16 and a source 13. Similarly, the select gate 11 forms the other portion of the transistor between the source 13 and the drain 16. The sense transistor 12 includes a channel 25a while the select transistor 14 includes a channel 24. The control gate forms the plate of the capacitor whose channel is 15a. The select gate 14, the floating gate 22 and the control gate 27 form the gates of a transistor with a source 13 and drain 16.

In the illustrated embodiment, the channels 25a and 24 are P-type semiconductor material and are part of a P-well 28. The P-well 28 in turn is formed in an N-well 29. Finally, the N-well 29 is formed in a P-type substrate 28. The P-well 28 may be biased, as indicated at 70, and the N-well 29 may be biased, as indicated at 72.

The floating gate 22 forms the tunneling capacitor 33 by its interaction with the channel 25a. A tunnel oxide 30 separates the floating gate 22 from the channel 25a. Similarly the interpoly dielectric oxide 40, which is part of a coupling capacitor 32, separates the floating gate 22 from the control gate 27. Finally, the control gate 27 is separated by the oxide 51 from the region 15a. Likewise the select transistor 14 includes a gate oxide 52, which may be of the same thickness as the tunnel oxide 30.

The overlaying of the control gate 27 over the select gate 11 is for processing convenience. Similarly, the control gate 27 is shown as overlaying the drain 16, but this too is merely for processing convenience. The control gate 27 need not be self-aligned to the sense or select transistors.

Programming is achieved by high efficiency substrate hot electron injection. As indicated in FIG. 8, substrate electrons, indicated by the arrows at 60, are generated by forward biasing the source 13 which is separated from the sense transistor 12 channel 25a by the select transistor channel 24 and the region 15a under the capacitor 50. Some of the substrate electrons 60 diffuse through the region underneath the channel 24 to the channel region 25a underneath the sense transistor 12.

For cells that need to be programmed, the channel region 25a is biased such that a depletion region 25 is formed. When an electron gets to the depletion region 62, it is accelerated by an electric field, Vcs. The electric field Vcs is the difference between the channel 25a potential (potential of the surface inversion region) and the P-well 28 potential. Some of the effective oxide barrier height potential, to be injected onto the floating gate 22.

For cells that are not to be programmed, the channel-to-P-well potential is less than the effective oxide barrier height. In such case, the electrons would not gain sufficient energy to overcome the barrier height and are not injected onto the floating gate 22.

The N+ doped region 13, the P-region 24 under the select transistor 14 and the sense transistor channel 25a form a lateral bipolar transistor 62. The emitter (source 13) of the bipolar transistor 62 acts as a charge injector, injecting substrate electrons from the source diffusion to the biased depletion region under the floating gate 22. With the diffusion 13 as the emitter and the channel 24 as the base, the collector is the biased depletion region 25 (including the region 15). Since the channel region 25a acts as the channel for the sense transistor during read, and the biased depletion region 25 under the sense transistor 12 acts as the collector of the bipolar transistor 62 during programming, a compact cell layout is achieved.

The efficiency of substrate hot electron injection is a function of a number of characteristics. Considering the depletion region 25, electrons scatter with lattice phonon scattering across the depletion region 25 with a certain electron means free path. Some of these electrons, without much scattering, gain sufficient energy to overcome the effective barrier height and are injected onto the floating gate 22. Some electrons gain less energy than the effective barrier height and are not injected onto the floating gate 22. The injection efficiency is a strong function of the doping concentrations and the channel-to-P-well potential, Vcs.

Since the cell 10 is situated in a P-well 28 embedded in an N-well 29, during programming the floating gate 22 is capacitively coupled to a higher voltage through the coupling capacitor 32 by raising the control gate 27 to Vpp, which may be from 7 to 14 volts. The voltage that the floating gate 22 attains at low drain bias is approximately a function of the voltage on the floating gate when the control gate 27 and the P-well 28 and drain 16 are at ground, plus the coupling ratio times the voltage on the control gate 27. The coupling ratio, to a first order, is approximately equal to the capacitance of the capacitor 32 divided by the sum of the capacitances of the coupling capacitor 32 and the tunneling capacitor 33.

When the selected transistor 14 is off, the sense transistor drain 16 potential can be forced close to the supply potential Vcc or higher. Since the select transistor 14 is off, the potential of node 51 follows the channel 25a potential. The channel 25a potential, which is the potential of the surface inversion region of the channel region 25a, is set as follows. When the potential of the floating gate 22 (Vfg) is one sense transistor 12 threshold voltage higher than the drain 16 potential, the channel potential is the same as the drain potential. On the other hand, when the floating gate 22 potential is less than the drain 16 potential plus the sense transistor 12 threshold voltage, the channel potential is the difference between the floating gate 22 voltage and the sense transistor 12 threshold voltage.

The P-well potential is the voltage 70 applied to the P-well 28. Since the P-well 28 is embedded in an N-well 29, and the N-well is set at a voltage 72 approximately Vss or higher, the P-well potential Vp can be negative, typically negative one to negative two volts. Moreover, it is usually less than the effective oxide barrier height to avoid any potential disturb problem.

The potential difference between the channel 25a region and the P-well 28 potential (Vp) 70 is the voltage across the depletion region 25. For cells to be programmed, the drain 16 voltage is raised high, typically close to Vcc or higher. A depletion region 25 in the channels 25a and 24 underneath the sense transistor 12 and the capacitor 50 is formed with a voltage drop equal to the channel potential minus the P-well potential 70.

For those cells that are not to be programmed, the drain 16 voltage 74 is set to zero volts (Vss). The voltage drop across the depletion region 25 then is equal to the absolute value of Vp, which is typically less than the effective oxide barrier height.

Cell 10 erasure is achieved by Fowler-Nordheim tunneling of electrons from the floating gate 22 to the channel region 25a and the drain diffusion 16. during erasure, the control gate 27 is forced to a negative voltage from −7 to −14 volts, for example. As for the drain diffusion 16, the P-well 28, and the N-well 29, they are biased to a positive potential close to Vcc or higher. Vcc is determined by the particular technology utilized. For example, it could be 5.0 to 2.5 volts with present technologies. This reduces the electric field across the junction between the N+ diffusion 16 and the P-well 28. The reduced field prevents acceleration of hot hole trapping in the gate oxide under the floating gate 22.

The drain 16 is preferably not biased to a voltage higher than the P-well 28 to such an extent that gate induced drain leakage (GIDL) becomes a problem. With current technologies, this means that the drain 16 bias can not be higher than the P-well 28 bias by about one volt. In addition, if the drain 16 bias significantly exceeds the P-well 28 bias, hot hole trapping may occur in the select gate oxide 52 due to the lateral junction field acceleration.

The ability to apply a positive voltage to the P-well arises because the P-well 28 is embedded in an N-well 29. The P-well voltage is preferably equal to or less than N-well potential to avoid P-well/N-well forward biasing. Thus, applying a positive voltage of Vcc or higher to the P-well, N-well and the drain 16 can eliminate hot hole trapping induced by GIDL while allowing the drain 16 voltage to be raised to Vcc or higher.

The voltage across the capacitor 33 is the difference between the floating gate 22 potential on the one hand and the diffusion 16 and P-well 28 potentials. When the difference exceeds 8 to 10 volts, sufficient tunneling current is generated and the floating gate 22 can be erased to a negative potential in the time frame of a few milliseconds to a few seconds, depending on the tunneling oxide 30 thickness.

Electrons tunnel to the drain region 16 (drain erase). The tunneling current depends on the voltage from the floating gate 22 to the drain 16.

Reading the programming state of the cell 10 may be accomplished as follows. The floating gate 22 is capacitively coupled to a higher potential by forcing the control gate 27 to a positive potential, for example, of 2.5 to 5 volts. The floating gate 22 is coupled to a potential Vfg which can be calculated as being equal to the sum of the floating gate potential when the control gate 27 is held at ground, plus the potential on the control gate 27 times the coupling ratio.

The drain 16 potential during reading is limited to a voltage of less than 2 volts. This is to avoid any read disturb.

For the selected cell to be read, the select gate 11 is forced to Vcc, and the source 13 is forced to ground. The unselected select gate 11 is also forced to ground.

When these potentials are applied to the selected cell 10, a current flows through the sense transistor 12. This current is then fed to a current sense amplifier (not shown). If the voltage on the floating gate 22 is greater than the threshold voltage on the sense transistor 12, a higher current, perhaps greater than 20 microamps, is detected as the conducting state. When the potential of the floating gate is less than the threshold voltage, a lower current, for example or less than one mircroamp flows, and a nonconducting state is detected.

A detected conducting state can be called a one state. A nonconducting state can be called the zero state.

An example of the operation of the cell in programming, reading and erasing is summarized in the following chart:

Cell Operation

| | |
|---|---|
| (Selected) | (Unselected) |

Erase

| | | |
|---|---|---|
| Drain (16) | ≧−Vcc | *0 or ≧−Vcc |
| Source (56) | Float | Float |
| Select (51) | Vss | Vss |
| Control (57) | −7 to −14 V | Vss |
| N-well (29) | ≧−Vcc | ≧−Vcc |
| P-well (28) | ≧−Vcc | ≧−Vcc |

Program

| | | |
|---|---|---|
| Drain (16) | ≧Vcc | *0 or ≧Vcc |
| Source (56) | Vs | Float |
| Select (51) | Vss-Vs | Vss-Vs |
| Control (57) | Vpp | Vss |
| N-well (29) | Vcc | Vcc |
| P-well (28) | Vbias | Vbias |

Read

| | | |
|---|---|---|
| Drain (16) | −1.5 V | *0 or −1.5 V |
| Source (56) | Vss | Vss |
| Select (51) | Vcc | Vss |
| Control (57) | 2-5 V | Vss |
| N-well (29) | Vcc | Vcc |
| P-well (28) | Vss | Vss |

*0 is for an unselected column.
Vpp = 7 to 14 volts.

Vs is the node voltage set by the injection current level, ranging from a few nanoamps to a few tens of microamps depending on the programming speed requirement. Typically it would be from tens of milliseconds to tens of microseconds. Vbias is the bias on the P-well 28 which can be Vss or it can be forced to −1 to −2 volts to enhance injection efficiency.

The cells in the array may be formed using conventional process technologies such as a double poly, single metal CMOS process. The illustrative parameters set forth herein contemplate a 0.25μ or lower feature size with Vcc potentials of 1.8 volts. As the technology permits lowering voltages and smaller feature sizes, the parameters herein would scale accordingly.

The starting substrate material is typically P-type (100) silicon, for example having a resistivity in the range of 10-20 ohm-cm. The P-well 28 is embedded in an N-well 29 in the so-called triple well process. The P-well 28 has a typical well depth of, for example, 2 to 4 μm with an average doping concentration, for example, in the range of 1×10¹⁶ to 5×10¹⁶ atoms per cubic centimeter.

The N-well 29 has a typical well depth of, for example, 4-8 μm. The doping concentration may be from 4×10¹⁵ to 1×10¹⁶ atoms per cubic centimeter. The triple well is formed by the P-well 28 counterdoping the N-well 29.

The formation of the elements in the triple well is as follows. An N-well implant is done, for example, with phosphorous 31 with a typical dose of 1 to 1.5×10¹³ atoms per square centimeter and an energy of 160 to 100 Kev. The N-well 29 is then counterdoped with a P-well implant. Typical dosages for the P-well implant could be 1.5 to 2.5×180 Kev using a species such as boron 11. The N-well 29 and P-well 28 are then driven, typically 6 to 10 hours at 1125 to 1150° C. This sets the wells to the desired doping concentrations and depths.

After the well formation, standard logic field oxide formation and channel stop formation steps are applied. The field oxide thickness and implant doses are adjusted to achieve a field threshold of 7 to 14 volts, which is determined by the Vpp level for programming and erasing and by logic process capability. After this formation, a memory cell implant may be performed. For example, a B11 implant at 30 to 50 Kev with a dose of 1.5 to 3×10¹³ atoms per square centimeter may be done through a sacrificial oxide. The gate oxide 52 and the tunnel oxide 30 are then formed. For example, an 85 to 100 Angstrom dry oxide may be grown across the wafer. A dry oxide is grown, for example, at 900° C. in partial oxygen followed by a 975 to 1050° C. anneal.

The floating gate 22 may then be formed of polysilicon, silicide or metals. If polysilicon is used, it can be 1600 Angstroms thick, and POCL3 doped at 870 to 1000° C. The interpoly dielectric is formed of an oxide-nitride-oxide sandwich (ONO) with the lower oxide being from 60 to 80 Angstroms, the nitride layer having a thickness of from 90 to 180 Angstroms and the upper oxide being from 30 to 40 Angstroms. A 125 to 200 Angstrom gate oxide may be grown for the oxide under the capacitor 50.

After floating gate and select gate definition, a N+ implant is implanted into the source of the select transistor 14 and the drain of the sense transistor 12. It is blocked between the two gates so that it does not enter the region under the plate of the capacitor 50, the N+ implant can be, for example, a phosphorous implant at 60 Kev, at a dose of 1 to 3×10¹⁴ atoms per square centimeter may be followed by arsenic at 60 Kev, 2.5 to 4.5×10¹⁵ atoms per square centimeter. It is also possible to form the source and drain using lightly doped drain (LDD) technology.

The polysilicon (poly 2) for the control gate may then be deposited and silicided if desired. The gates are patterned and defined using standard techniques. The control gate is not self-aligned to the sense and select gates.

With the completion of these capacitor and transistor structures, all subsequent processing for contacts and interconnect layers follows standard logic rear end processing.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A content addressable memory cell comprising:
a non-volatile memory storage transistor; and
an enhancement transistor coupled in series to said storage transistor.

2. The cell of claim 1 including a pair of storage transistors each coupled to an enhancement transistor.

3. The cell of claim 1 including a bias line coupled to said enhancement transistor.

4. The cell of claim 3 wherein a word line is coupled to said storage transistor.

5. The cell of claim 4 including an injector coupled to said storage transistor.

6. The cell of claim 1 wherein said cell is a single polysilicon cell.

7. The cell of claim 1 wherein said cell is a double polysilicon cell.

8. The cell of claim 1 wherein said storage transistor uses substrate hot electron injection.

9. The cell of claim 1 including a pair of storage transistors and a pair of enhancement transistors, a first storage cell and a first enhancement transistor coupled to a data line and a second storage cell and second enhancement transistor coupled to a complement data line.

10. The cell of claim 9 including a node between the coupled first storage transistor and first enhancement transistor and the coupled second storage transistor and second enhancement transistor, said node coupled to a match line of said cell.

11. A method of comparing data using a content addressable memory comprising:
receiving information on a data and a data bar line;
comparing that information to information stored on a non-volatile memory storage transistor coupled to an enhancement transistor.

12. The method of claim 11 including providing said enhancement transistor in series with said storage transistor.

13. The method of claim 12 including providing a bias line to control the conduction of said enhancement transistor.

14. The method of claim 13 including using said bias line to shut off said enhancement transistor.

15. The method of claim 11 including controlling the voltage at the node between said storage and enhancement transistors.

16. The method of claim 15 including maintaining said node at about one volt or less.

17. The method of claim 16 including reducing the read disturb problem by limiting the voltage excursion on said node.

18. The method of claim 11 including coupling a first storage transistor and series enhancement transistor to the data bar line and coupling a second storage transistor and series enhancement transistor to the data line.

19. The method of claim 18 including coupling a node between said first and second storage transistors to the match line of a content addressable memory.
